(19) United States
(12) Patent Application Publication
(10) Pub. No.: US 2024/0206143 A1
(43) Pub. Date: Jun. 20, 2024

(54) COMPONENT SUPPLY DEVICE AND COMPONENT MOUNTING DEVICE

(71) Applicant: YAMAHA HATSUDOKI KABUSHIKI KAISHA, Iwata-shi, Shizuoka (JP)

(72) Inventors: Yukinari AWANO, Iwata-shi (JP); Ayaka KANAZAWA, Iwata-shi (JP)

(73) Assignee: YAMAHA HATSUDOKI KABUSHIKI KAISHA, Iwata-shi, Shizuoka (JP)

(21) Appl. No.: 18/554,784

(22) PCT Filed: Apr. 16, 2021
(86) PCT No.: PCT/JP2021/015776

§ 371 Date: Oct. 10, 2023

(51) Int. Cl. H05K 13/04

(52) U.S. Cl. CPC H05K 13/0419

(57) ABSTRACT

A component supply device includes a feed sprocket to feed a component supply tape toward a discharge passage, and a discharge sprocket in the discharge passage. The discharge sprocket has teeth that are insertable simultaneously into sprocket holes of both a following tape corresponding to the subsequent component supply tape in use and a leading tape corresponding to the used preceding component supply tape. The component supply device is operable to rotate the discharge sprocket to feed the leading tape in the discharge passage.

### CROSS-REFERENCE TO RELATED APPLICATION

This application is a National Stage of International Patent Application No. PCT/JP2022/015776, filed Apr. 16, 2021, the entire content of which is incorporated herein by reference.

### BACKGROUND

### Technical Field

The present disclosure relates to a component supply device and a component mounting device, and more particularly, it relates to a component supply device and a component mounting device, both of which supply components using component supply tapes.

### Background Art

Conventionally, a component supply device that supplies components using component supply tapes is known. Such a device is disclosed in Japanese Patent Laying-Open No. 2019-117825, for example.

Japanese Patent Laying-Open No. 2019-117825 discloses a tape feeder (component supply device) that supplies components using carrier tapes (component supply tapes). This tape feeder is configured to convey a leading tape, which is a carrier tape that leads the other, and a following tape, which is a carrier tape that is fed after the leading tape.

### SUMMARY

Although not clearly described in Japanese Patent Laying-Open No. 2019-117825, in the tape feeder described in Japanese Patent Laying-Open No. 2019-117825, the used leading tape is conceivably pushed out by the following tape and discharged. However, when the leading tape is pushed out by a tip end of the following tape and discharged, the following tape may ride on the leading tape to overlap the leading tape, for example. In this case, the leading tape cannot be pushed out by the tip end of the following tape, and thus it is difficult to smoothly discharge the leading tape.

Accordingly, the present disclosure provides a component supply device and a component mounting device each capable of smoothly discharging a leading tape from a discharge passage even when a following tape overlaps the leading tape.

A component supply device according to a first aspect of the present disclosure includes a feed sprocket to feed a component supply tape holding a component to a component supply position, and feed the component supply tape from which the component has been taken out at the component supply position toward a discharge passage, and a discharge sprocket in the discharge passage. The discharge sprocket has teeth that are insertable simultaneously into sprocket holes of both a following tape corresponding to a subsequent component supply tape in use and a leading tape corresponding to a used preceding component supply tape, and the component supply device is operable to rotate the discharge sprocket to feed the leading tape in the discharge passage.

As described above, the component supply device according to the first aspect of the present disclosure includes the discharge sprocket in the discharge passage. The discharge sprocket has the teeth that are insertable simultaneously into the sprocket holes of both the following tape corresponding to the subsequent component supply tape in use and the leading tape corresponding to the used preceding component supply tape. The component supplier is operable to rotate the discharge sprocket to feed the leading tape in the discharge passage. Accordingly, even when the following tape rides on the leading tape to overlap the leading tape, for example, the leading tape can be fed by the discharge sprocket. Consequently, even when the following tape overlaps the leading tape, the leading tape can be smoothly discharged from the discharge passage.

In the component supply device according to the first aspect, the discharge sprocket preferably does not have power, and the component supply device is preferably operable to rotate the discharge sprocket to feed the leading tape in the discharge passage by feeding the following tape by a driving force of the feed sprocket while the teeth of the discharge sprocket are inserted simultaneously into the sprocket holes of both the following tape and the leading tape. Accordingly, unlike a case in which the discharge sprocket has power, it is not necessary to provide a drive such as a motor to drive the discharge sprocket. Consequently, the structure of a discharge mechanism including the discharge sprocket can be simplified and downsized. Furthermore, being able to downsize the discharge mechanism including the discharge sprocket is very effective when the discharge sprocket is provided in the discharge passage in which an installation space is relatively small.

In the component supply device according to the first aspect, a height of each of the teeth is preferably larger than a thickness of the component supply tape. Accordingly, unlike a case in which the height of each of the teeth of the discharge sprocket is equal to or less than the thickness of the component supply tape, the teeth of the discharge sprocket can be reliably inserted simultaneously into both the sprocket holes of both the following tape (components supply tape) and the leading tape (components supply tape). Consequently, both the following tape and the leading tape can be reliably fed by rotation of the discharge sprocket.

The component supply device according to the first aspect preferably further includes an urging force generator to urge one of the discharge sprocket and the component supply tape toward the other of the discharge sprocket and the component supply tape. Accordingly, due to the urging force of the urging force generator, the discharge sprocket and the component supply tape can be placed close to each other. Consequently, the teeth of the discharge sprocket can be reliably inserted into the sprocket holes of the component supply tape.

In the component supply device according to the first aspect, a diameter of the discharge sprocket is preferably smaller than a diameter of the feed sprocket, and a number of the teeth of the discharge sprocket is preferably less than a number of teeth of the feed sprocket. Accordingly, the discharge sprocket can be downsized. Consequently, the discharge sprocket can be easily arranged even in the discharge passage in which the installation space is relatively small.

In this case, a pitch between the teeth of the discharge sprocket is preferably smaller than a pitch between the teeth of the feed sprocket. In the small discharge sprocket having a smaller diameter than the feed sprocket, when the pitch between the teeth of the discharge sprocket is the same as the pitch between (the roots of) the teeth of the large feed sprocket having a larger diameter, the tip ends of the teeth may be too far apart unlike the feed sprocket that is larger than the discharge sprocket. Therefore, the teeth of the discharge sprocket may not be inserted (fitted) into the sprocket holes of the component supply tape one after another. Therefore, as described above, the pitch between the teeth of the discharge sprocket is smaller than the pitch between the teeth of the feed sprocket. Thus, even when the discharge sprocket is smaller than the feed sprocket, the teeth of the discharge sprocket can be inserted (fitted) into the sprocket holes of the component supply tape one after another. Consequently, the component supply tape (the following tape and the leading tape) can be reliably fed by rotation of the discharge sprocket.

In the structure in which the pitch between the teeth of the discharge sprocket is smaller than the pitch between the teeth of the feed sprocket, a width of each of the teeth of the discharge sprocket is preferably smaller than a width of each of the teeth of the feed sprocket. Accordingly, the width of each of the teeth of the discharge sprocket can be relatively small. Consequently, the teeth of the discharge sprocket can be more easily inserted (fitted) into the sprocket holes of the component supply tape as compared with a case in which the width of each of the teeth of the discharge sprocket is relatively large.

The component supply device according to the first aspect preferably further includes a bending habit correction mechanism in the discharge passage to correct a bending habit of the component supply tape, and the discharge sprocket is preferably provided in the discharge passage together with the bending habit correction mechanism. Accordingly, even when the bending habit correction mechanism is provided such that the discharge passage becomes complex, the leading tape can be smoothly discharged from the discharge passage by the discharge sprocket.

A component mounting device according to a second aspect of the present disclosure includes a mounting head to hold and mount a component on a board, and a component supplier to supply the component to the mounting head. The component supplier includes a feed sprocket to feed a component supply tape holding the component to a component supply position, and feed the component supply tape from which the component has been taken out at the component supply position toward a discharge passage, and a discharge sprocket in the discharge passage. The discharge sprocket has teeth that are insertable simultaneously into sprocket holes of both a following tape corresponding to the subsequent component supply tape in use and a leading tape corresponding to the used preceding component supply tape, and the component supplier is operable to rotate the discharge sprocket to feed the leading tape in the discharge passage.

As described above, the component mounting device according to the second aspect of the present disclosure includes the discharge sprocket in the discharge passage. The discharge sprocket has the teeth that are insertable simultaneously into the sprocket holes of both the following tape corresponding to the subsequent component supply tape in use and the leading tape corresponding to the used preceding component supply tape. The component supplier is operable to rotate the discharge sprocket to feed the leading tape in the discharge passage. Accordingly, even when the following tape rides on the leading tape to overlap the leading tape, for example, the leading tape can be fed by the discharge sprocket. Consequently, it is possible to provide the component mounting device capable of smoothly discharging the leading tape from the discharge passage even when the following tape overlaps the leading tape. Furthermore, an error caused by not discharging the leading tape can be reduced or prevented, and thus a decrease in the productivity of the component mounting device can be reduced or prevented.

In the component mounting device according to the second aspect, the discharge sprocket preferably does not have power, and the component supplier is preferably operable to rotate the discharge sprocket to feed the leading tape in the discharge passage by feeding the following tape by a driving force of the feed sprocket while the teeth of the discharge sprocket are inserted simultaneously into the sprocket holes of both the following tape and the leading tape. Accordingly, unlike a case in which the discharge sprocket has power, it is not necessary to provide a drive to drive the discharge sprocket. Consequently, the structure of a discharge mechanism including the discharge sprocket can be simplified and downsized. Furthermore, being able to downsize the discharge mechanism including the discharge sprocket is very effective in the structure in which the discharge sprocket is provided in the discharge passage in which an installation space is relatively small.

According to the present disclosure, as described above, it is possible to provide the component supply device and the component mounting device each capable of smoothly discharging the leading tape from the discharge passage even when the following tape overlaps the leading tape.

### BRIEF DESCRIPTION OF THE DRAWINGS

FIG. 1 is a plan view schematically showing a component mounting device according to a first embodiment;

FIG. 2 is a block diagram showing the control structure of the component mounting device according to the first embodiment;

FIG. 3 is a side view schematically showing a component supplier according to the first embodiment;

FIG. 4 is a perspective view showing a component supply tape according to the first embodiment;

FIG. 5 is a side view schematically showing a component supply tape discharger of the component supplier according to the first embodiment;

FIG. 6 is a perspective view showing the component supply tape discharger of the component supplier according to the first embodiment;

FIG. 7 is a first diagram for illustrating component supply tape discharge of the component supplier according to the first embodiment;

FIG. 8 is a second diagram for illustrating component supply tape discharge of the component supplier according to the first embodiment;

FIG. 9 is a third diagram for illustrating component supply tape discharge of the component supplier according to the first embodiment;

FIG. 10 is a diagram showing a discharge sprocket of the component supplier according to the first embodiment;

FIG. 11 is a diagram showing a feed sprocket of the component supplier according to the first embodiment;

FIG. 12 is a first diagram for illustrating insertion of discharge sprocket teeth into sprocket holes of the component supply tape according to the first embodiment;

FIG. 13 is a second diagram for illustrating insertion of the discharge sprocket teeth into the sprocket holes of the component supply tape according to the first embodiment;

FIG. 14 is a first diagram for illustrating insertion of discharge sprocket teeth into sprocket holes of a component supply tape according to a comparative example;

FIG. 15 is a second diagram for illustrating insertion of the discharge sprocket teeth into the sprocket holes of the component supply tape according to the comparative example;

FIG. 16 is a side view schematically showing a component supplier according to a second embodiment; and

FIG. 17 is a diagram for illustrating component supply tape discharge of the component supplier according to the second embodiment.

### DETAILED DESCRIPTION

Embodiments embodying the present disclosure are hereinafter described on the basis of the drawings.

### First Embodiment

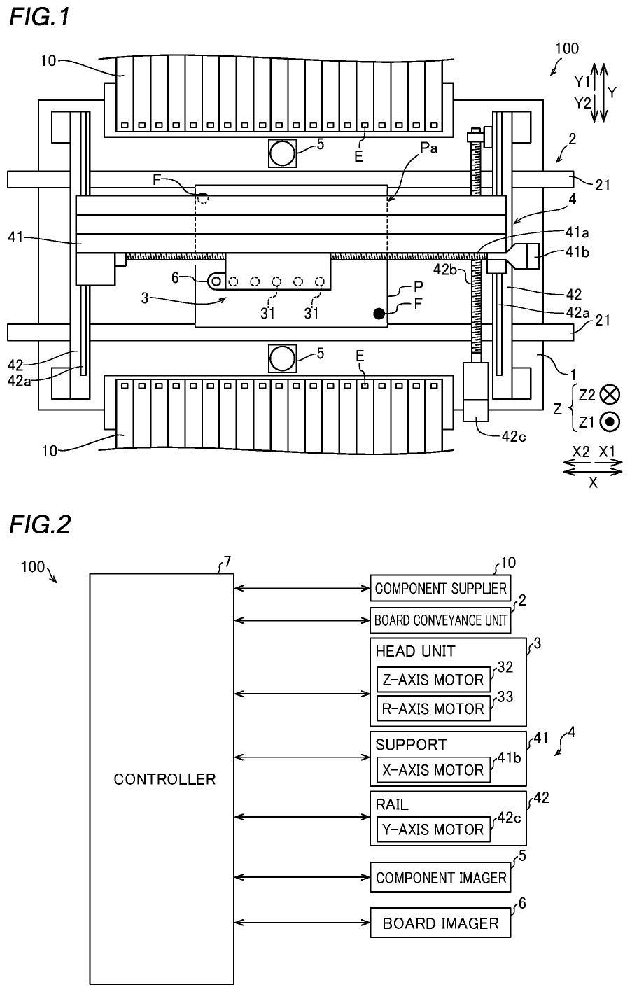

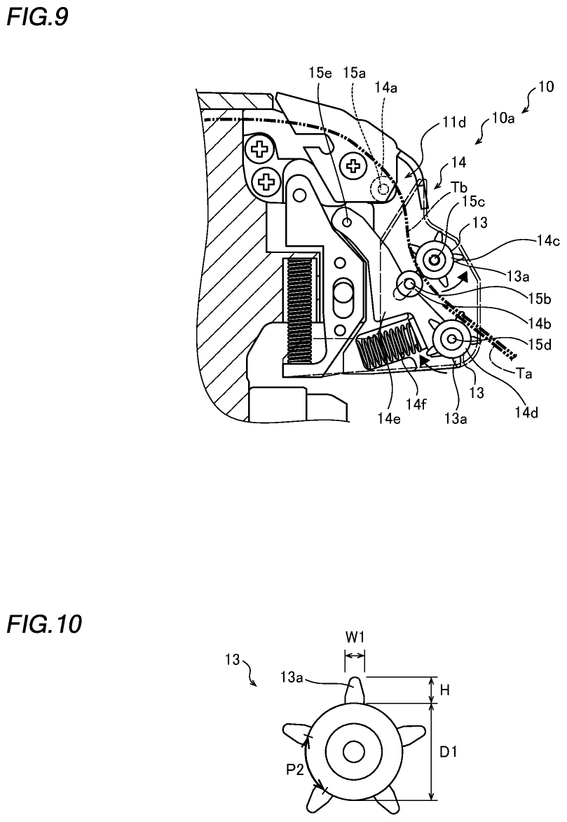

The structure of a component mounting device 100 according to a first embodiment of the present disclosure is described with reference to FIGS. 1 to 15.

### Structure of Component Mounting Device

As shown in FIGS. 1 and 2, the component mounting device 100 is a device that mounts components E (electronic components) such as ICs, transistors, capacitors, and resistors on a board P such as a printed circuit board.

The component mounting device 100 includes a base 1, a board conveyance unit 2, a head unit 3, a head horizontal movement mechanism 4, component imagers 5, a board imager 6, a controller 7 (see FIG. 2), and component suppliers 10. The component suppliers 10 are examples of a “component supply device” in the claims.

The base 1 is a base on which each constituent component is arranged in the component mounting device 100. On the base 1, the board conveyance unit 2, a rail 42 described below, and the component imagers 5 are provided. The controller 7 is provided in the base 1. Furthermore, on the base 1, a plurality of component suppliers 10 are arranged on opposite sides (a Y1 direction side and a Y2 direction side) in a Y direction. The board conveyance unit 2 carries in the board P before mounting, conveys the board P in a board conveyance direction (X direction), and carries out the board P after mounting. The board conveyance unit 2 conveys the carried-in board P to a mounting stop position Pa and fixes the board P at the mounting stop position Pa by a board fixing mechanism (not shown) such as a clamp mechanism. The board conveyance unit 2 includes a pair of conveyance belts 21, and conveys the board P in the board conveyance direction while supporting both ends of the board P in a width direction (Y direction) from below (Z2 direction side) by the pair of conveyance belts 21, respectively.

The head unit 3 is a head unit for component mounting. The head unit 3 mounts the components E on the board P fixed at the mounting stop position Pa. Specifically, the head unit 3 includes a plurality of (five) mounting heads 31. The mounting heads 31 hold and mount the components E on the board P. Specifically, the mounting heads 31 include detachable suction nozzles (not shown) at tip ends of the mounting heads 31 to suction the components E. The mounting heads 31 cause the suction nozzles to hold (suction) the components E by a negative pressure supplied from a negative pressure supplier (not shown).

The head unit 3 includes a Z-axis motor 32 (see FIG. 2) to move the suction nozzle of each mounting head 31 in an upward-downward direction (Z direction), and an R-axis motor 33 (see FIG. 2) to rotate the suction nozzle of each mounting head 31 about a rotation axis that extends in the upward-downward direction. The mounting heads 31 are movable in the upward-downward direction between predetermined lowered positions and predetermined raised positions with the Z-axis motor 32. Furthermore, the mounting heads 31 can adjust the orientations of the held components E by being rotated by the R-axis motor 33 while holding the components E.

The head horizontal movement mechanism 4 moves the head unit 3 in a horizontal direction (the X direction and the Y direction). The head horizontal movement mechanism 4 includes a support 41 to support the head unit 3 such that the head unit 3 is movable in the board conveyance direction (X direction), and the rail 42 to support the support 41 such that the support 41 is movable in a direction (Y direction) perpendicular to the board conveyance direction in a horizontal plane. The support 41 includes a ball screw shaft 41a that extends in the board conveyance direction and an X-axis motor 41b to rotate the ball screw shaft 41a. On the head unit 3, a ball nut (not shown) that engages with the ball screw shaft 41a of the support 41 is provided. The ball screw shaft 41a is rotated by the X-axis motor 41b such that the head unit 3 is movable in the board conveyance direction along the support 41 together with the ball nut that engages with the ball screw shaft 41a.

The rail 42 includes a pair of guide rails 42a to support both ends of the support 41 in the X direction such that the support 41 is movable in the Y direction, a ball screw shaft 42b that extends in the Y direction, and a Y-axis motor 42c to rotate the ball screw shaft 42b. On the support 41, a ball nut (not shown) that engages with the ball screw shaft 42b of the rail 42 is provided. The ball screw shaft 42b is rotated by the Y-axis motor 42c such that the support 41 is movable in the Y direction along the pair of guide rails 42a of the rail 42 together with the ball nut that engages with the ball screw shaft 42b.

The head unit 3 is movable in the horizontal direction above the base 1 by the support 41 and the rail 42 of the head horizontal movement mechanism 4. Thus, the mounting heads 31 of the head unit 3 can move above the component suppliers 10 and hold the components E supplied from the component suppliers 10. Furthermore, the mounting heads 31 of the head unit 3 can move above the board P fixed at the mounting stop position Pa and mount the held components E on the board P.

The component imagers 5 are cameras for component recognition. The component imagers 5 image the components E held by the suction nozzles of the mounting heads 31 during conveyance of the components E to the board P by the mounting heads 31 of the head unit 3. The component imagers 5 are fixed on the upper surface of the base 1, and image the components E held by the nozzle nozzles of the mounting heads 31 from the lower side (Z2 direction side) of the components E. Based on the imaging results of the components E by the component imagers 5, the controller 7 acquires (recognizes) the states (rotating postures and suctioned positions with respect to the mounting heads 31) of the components E.

The board imager 6 is a camera for board recognition. The board imager 6 images position recognition marks F (fiducial marks) attached to the upper surface of the board P fixed at the mounting stop position Pa before the mounting heads 31 of the head unit 3 start mounting the components E on the board P. The position recognition marks F are marks for recognizing the position of the board P. Based on the imaging results of the position recognition marks F by the board imager 6, the controller 7 acquires (recognizes) the precise position and posture of the board P fixed at the mounting stop position Pa.

As shown in FIG. 2, the controller 7 is a control circuit that controls the operation of the component mounting device 100. The controller 7 includes a processor such as a central processing unit (CPU), and memories such as a read-only memory (ROM) and a random access memory (RAM). The controller 7 performs a control to cause the head unit 3 to mount the components E on the board P by controlling the board conveyance unit 2, the component suppliers 10, the X-axis motor 41b, and the Y-axis motor 42c, for example, according to production programs.

### Structure of Component Supplier

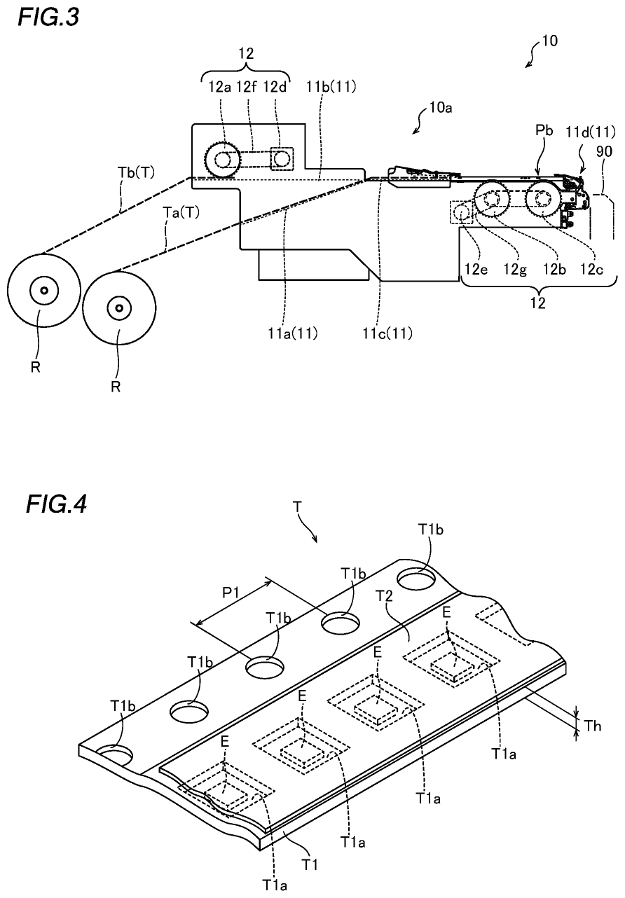

As shown in FIG. 3, the component supplier 10 is a tape feeder that supplies the components E using a component supply tape T. The component supply tape T is supplied from a reel R and is wound around the axle of the reel R. The component supplier 10 feeds the component supply tape T supplied from the reel R to a component supply position Pb (a component holding position, a component suction position). The component supply position Pb is a position at which the mounting heads 31 of the head unit 3 acquire the components E.

As shown in FIG. 4, The component supply tape T holds the components E. Specifically, the component supply tape T includes a carrier tape T1 and a cover tape T2. Recesses T1a for accommodating (storing) the components E, and sprocket holes T1b that engage with the teeth of a sprocket are formed in the carrier tape T1. The recesses T1a are formed at a predetermined pitch along a direction in which the carrier tape T1 (component supply tape T) extends. The sprocket holes T1b are formed at a predetermined pitch P1 along the direction in which the carrier tape T1 (component supply tape T) extends. The cover tape T2 is attached to the upper surface of the carrier tape T1 by pressure bonding or heat sealing, for example. The cover tape T2 covers a plurality of recesses T1a of the carrier tape T1 from above. Although detailed description is omitted, the cover tape T2 is opened by a component exposing mechanism (not shown) of the component supplier 10 before the component supply position Pb.

As shown in FIG. 3, the component supplier 10 includes a main body 10a. A tape passage 11 is provided in the main body 10a. The tape passage 11 is a passage formed in the main body 10a, through which the component supply tape T passes. The tape passage 11 includes a first passage 11a through which a leading tape Ta that is a preceding component supply tape T passes, and a second passage 11b through which a following tape Tb that is a subsequent component supply tape T passes. The tape passage 11 also includes a third passage 11c provided downstream of the first passage 11a and the second passage 11b in a feeding direction and serving as a confluence passage of the first passage 11a and the second passage 11b. Depending on the supply state, either the leading tape Ta or the following tape Tb passes through the third passage 11c. When there is no need to distinguish between the leading tape Ta and the following tape Tb, the leading tape Ta and the following tape Tb are simply referred to as the component supply tape T.

As described above, the first passage 11a and the second passage 11b are provided as the tape passage 11 in the main body 10a such that the following tape Tb for replenishing the components E can be arranged in advance in the main body 10a. Thus, after the leading tape Ta has been used up, the following tape Tb can be rapidly supplied to replenish the components E without performing the splicing operation. The component supplier 10 is an auto-loading feeder that automatically feeds the following tape Tb and starts using the following tape Tb when the use of the leading tape Ta is finished. FIG. 3 shows a state in which the leading tape Ta passes through the first passage 11a and the third passage 11c, and the following tape Tb passes through the second passage 11b.

The main body 10a includes a tape feeding mechanism 12 to feed the component supply tape T. The tape feeding mechanism 12 feeds the component supply tape T along the tape passage 11. Specifically, the tape feeding mechanism 12 includes a plurality of (three) sprockets 12a, 12b, and 12c and a plurality of (two) drive motors 12d and 12e. The sprockets 12a, 12b, and 12c have teeth that are inserted into the sprocket holes T1b of the component supply tape T. The sprockets 12a, 12b, and 12c feed the component supply tape T by rotating with the teeth inserted into the sprocket holes T1b of the component supply tape T. The sprockets 12b and 12c are examples of a “feed sprocket” in the claims.

The sprockets 12a, 12b, and 12c are arranged in this order from the upstream side to the downstream side in the feeding direction. The sprocket 12a is arranged in a portion of the main body 10a on the upstream side in the feeding direction. The sprocket 12a is arranged in the vicinity of an entrance of the second passage 11b. The sprocket 12a feeds the component supply tape T introduced from the entrance of the second passage 11b to the sprocket 12b arranged on the downstream side.

The Sprockets 12b and 12c are arranged in a portion of the main body 10a on the downstream side in the feeding direction. The sprockets 12b and 12c are arranged at positions corresponding to the component supply position Pb (positions in the vicinity of the component supply position Pb). The sprockets 12b and 12c feed the component supply tape T to the component supply position Pb. The sprockets 12b and 12c feed the component supply tape T from which the components E have been taken out at the component supply position Pb toward a discharge passage 11d. The discharge passage 11d is a portion of the tape passage 11 through which the component supply tape T from which the components E have been taken out at the component supply position Pb passes. The component supply tape T that has passed through the discharge passage 11d is discharged into a cutter slope 90 provided separately from the component supplier 10 in the component mounting device 100. The discharge passage 11d is provided at a tip end of the main body 10a of the component supplier 10.

The drive motor 12d is a motor that rotates the sprocket 12a. The drive motor 12d is connected to the sprocket 12a by a driving force transmission mechanism 12f that transmits the driving force of the drive motor 12d to the sprocket 12a. The driving force transmission mechanism 12f is a belt-pulley mechanism, for example. The driving force transmission mechanism 12f may be a gear mechanism. The drive motor 12e is a motor that rotates the sprockets 12b and 12c. The drive motor 12e is connected to the sprockets 12b and 12c by a driving force transmission mechanism 12g that transmits the driving force of the drive motor 12e to the sprockets 12b and 12c. The sprockets 12b and 12c are synchronously driven by the single drive motor 12e. The driving force transmission mechanism 12g is a belt-pulley mechanism, for example. The driving force transmission mechanism 12g may be a gear mechanism.

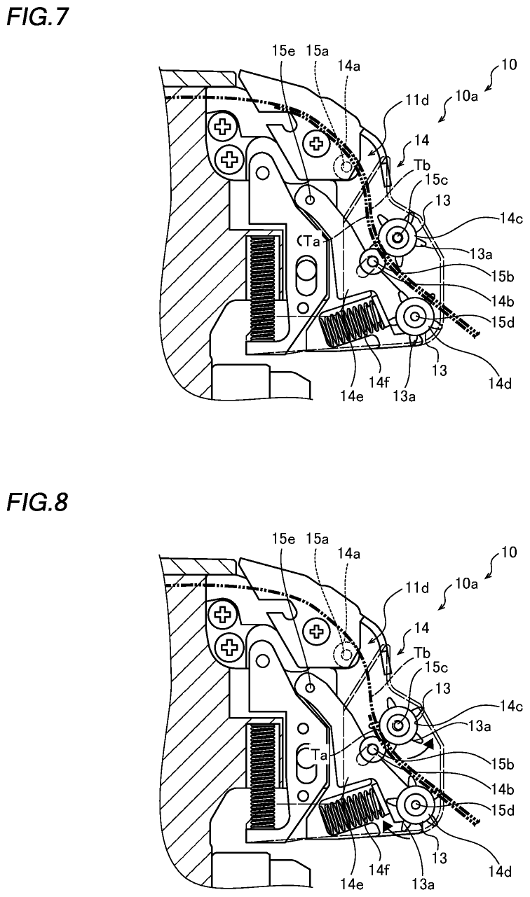

When the leading tape Ta is used up in the component supplier 10, the used leading tape Ta is pushed out by a tip end of the following tape Tb and is discharged from the discharge passage 11d. However, when the following tape Tb rides on the leading tape Ta to overlap the leading tape Ta, for example (see FIG. 7), the leading tape Ta cannot be pushed out by the tip end of the following tape Tb and cannot be discharged from the discharge passage 11d. When the leading tape Ta cannot be pushed out by the tip end of the following tape Tb and cannot be discharged from the discharge passage 11d, the tip end of the leading tape Ta protruding from the discharge passage 11d is inserted into the cutter slope 90, and thus the leading tape Ta may get caught on the cutter slope 90 when the component supplier 10 is removed from the component mounting device 100. In this case, when the leading tape Ta remains caught on the cutter slope 90 when the component supplier 10 is reattached to the component mounting device 100, the leading tape Ta may be sandwiched between the component supplier 10 and the cutter slope 90, and the sandwiched leading tape Ta may obstruct discharge of the subsequent component supply tape T. In this case, an error may occur, and the productivity of the component mounting device 100 may decrease.

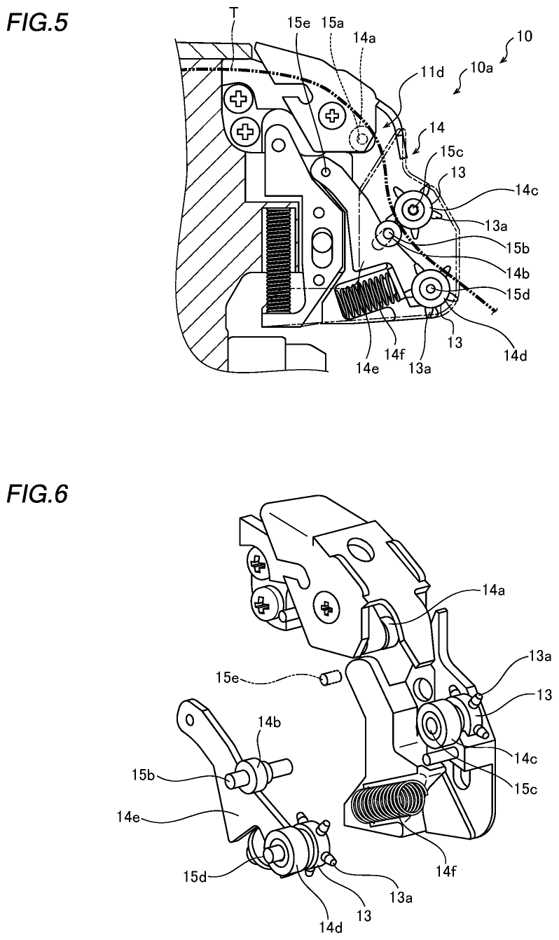

Therefore, as shown in FIGS. 5 to 9, in the first embodiment, the component supplier 10 includes discharge sprockets 13 provided in the discharge passage 11d. Each of the discharge sprockets 13 has teeth 13a that can be inserted simultaneously into the sprocket holes T1b of both the following tape Tb, which is the subsequent component supply tape T in use, and the leading tape Ta, which is the used preceding component supply tape T. Furthermore, in the component supplier 10, the leading tape Ta in the discharge passage 11d is fed by rotating the discharge sprockets 13.

In the first embodiment, each of the discharge sprockets 13 does not have power (is not driven by a motor). In the component supplier 10, the following tape Tb is fed by the driving force of the sprockets 12b and 12c (the driving force of the drive motor 12e) while the teeth 13a of the discharge sprockets 13 are inserted simultaneously into the sprocket holes T1b of both the following tape Tb and the leading tape Ta such that the discharge sprockets 13 are rotated to feed the leading tape Ta in the discharge passage 11d.

Specifically, in the component supplier 10, when the following tape Tb is fed while the teeth 13a of the discharge sprockets 13 are inserted simultaneously into the sprocket holes T1b of both the following tape Tb and the leading tape Ta, the sprocket holes T1b of the following tape Tb contact the teeth 13a of the discharge sprockets 13 such that the driving force of the following tape Tb is transmitted to the discharge sprockets 13, and the discharge sprockets 13 are rotated. Furthermore, in the component supplier 10, when the sprocket holes T1b of the following tape Tb contact the teeth 13a of the discharge sprockets 13 such that the discharge sprockets 13 are rotated, the teeth 13a of the discharge sprockets 13 contact the sprocket holes T1b of the leading tape Ta. Thus, the driving force of the discharge sprockets 13 is transmitted to the leading tape Ta, and the leading tape Ta overlapping the following tape Tb in the discharge passage 11d is fed.

A plurality of (two) discharge sprockets 13 are provided. One of the two discharge sprockets 13 is provided in the vicinity of a central portion of the discharge passage 11d. The other of the two discharge sprockets 13 is provided in the vicinity of an exit of the discharge passage 11d. The two discharge sprockets 13 are provided on a first side and a second side with respect to the component supply tape T. The teeth 13a of one of the two discharge sprockets 13 are inserted into the sprocket holes T1b of the component supply tape T from above. The teeth 13a of the other of the two discharge sprockets 13 are inserted into the sprocket holes T1b of the component supply tape T from below. Each of the discharge sprockets 13 has a plurality of teeth 13a. The plurality of teeth 13a are provided at substantially equal angular intervals in a circumferential direction.

In the first embodiment, the component supplier 10 includes a bending habit correction mechanism 14 that corrects bending of the component supply tape T. The bending habit correction mechanism 14 is provided in the discharge passage 11d. The bending habit of the component supply tape T is a curling habit formed on the component supply tape T when the component supply tape T is wound around the reel R. In the first embodiment, the discharge sprockets 13 are provided in the discharge passage 11d together with the bending habit correction mechanism 14.

The bending habit correction mechanism 14 corrects the bending habit of the component supply tape T by bending the component supply tape T in a direction opposite to a bending habit direction. Specifically, the bending habit correction mechanism 14 includes a plurality of (four) rollers 14a, 14b, 14c, and 14d, a lever 14e, and an urging force generator 14f. The plurality of rollers 14a, 14b, 14c, and 14d support and guide the component supply tape T in the discharge passage 11d. Furthermore, the plurality of rollers 14a, 14b, 14c, and 14d are placed so as to bend the component supply tape T in the direction opposite to the bending habit direction.

The roller 14a is arranged at the uppermost position among the plurality of rollers 14a, 14b, 14c, and 14d. The roller 14a is rotatably supported by a rotation shaft 15a. The rollers 14b and 14c are arranged at middle positions among the plurality of rollers 14a, 14b, 14c, and 14d. The rollers 14b and 14c sandwich the component supply tape T. The rollers 14b and 14c are rotatably supported by rotation shafts 15b and 15c, respectively. The rotation shaft 15c supports the discharge sprocket 13 (upstream discharge sprocket) such that the discharge sprocket 13 is rotatable. The roller 14c and the discharge sprocket 13 are supported by the common rotation shaft 15c. The roller 14d is arranged at a lower position among the plurality of rollers 14a, 14b, 14c, and 14d. The roller 14d is rotatably supported by a rotation shaft 15d. The rotation shaft 15d supports the discharge sprocket 13 (downstream discharge sprocket) such that the discharge sprocket 13 is rotatable. The roller 14d and the discharge sprocket 13 are supported by the common rotation shaft 15d.

The lever 14e is rotatably supported by a rotation shaft 15e provided in the main body 10a. The lever 14e is rotatable about the rotation shaft 15e by the urging force of the urging force generator 14f. The rollers 14b and 14d are integrally and rotatably provided on the lever 14e. The roller 14b is provided in the vicinity of a central portion of the lever 14e. The roller 14d is provided at an end of the lever 14e on the side opposite to the rotation shaft 15e side. The lever 14e presses the rollers 14b and 14d against the component supply tape T by the urging force of the urging force generator 14f. Furthermore, the discharge sprocket 13 (downstream discharge sprocket) is integrally and rotatably provided on the lever 14e together with the roller 14d.

The urging force generator 14f is a coil spring having an urging force. The urging force generator 14f urges the lever 14e. Specifically, the urging force generator 14f urges the rollers 14b and 14d toward the component supply tape T via the lever 14e. In the first embodiment, the urging force generator 14f urges the component supply tape T toward the discharge sprocket 13 (upstream discharge sprocket) via the lever 14e and the roller 14b. Furthermore, in the first embodiment, the urging force generator 14f urges the discharge sprocket 13 (downstream discharge sprocket) toward the component supply tape T via the lever 14e. Moreover, it is possible to handle component supply tapes T having different thicknesses by the urging force of the urging force generator 14f.

As shown in FIGS. 4 and 10, in the first embodiment, the height H (see FIG. 10) of each of the teeth 13a of each of the discharge sprockets 13 is larger than the thickness Th (see FIG. 4) of the component supply tape T (carrier tape T1). That is, the height H (see FIG. 10) of each of the teeth 13a of each of the discharge sprockets 13 is large enough to allow simultaneous insertion into the sprocket holes T1b (the sprocket holes of both the leading tape Ta and the following tape Tb) of the two overlapping component supply tapes T. The thickness Th of the component supply tape T refers to the maximum thickness of a plurality of types of component supply tapes T.

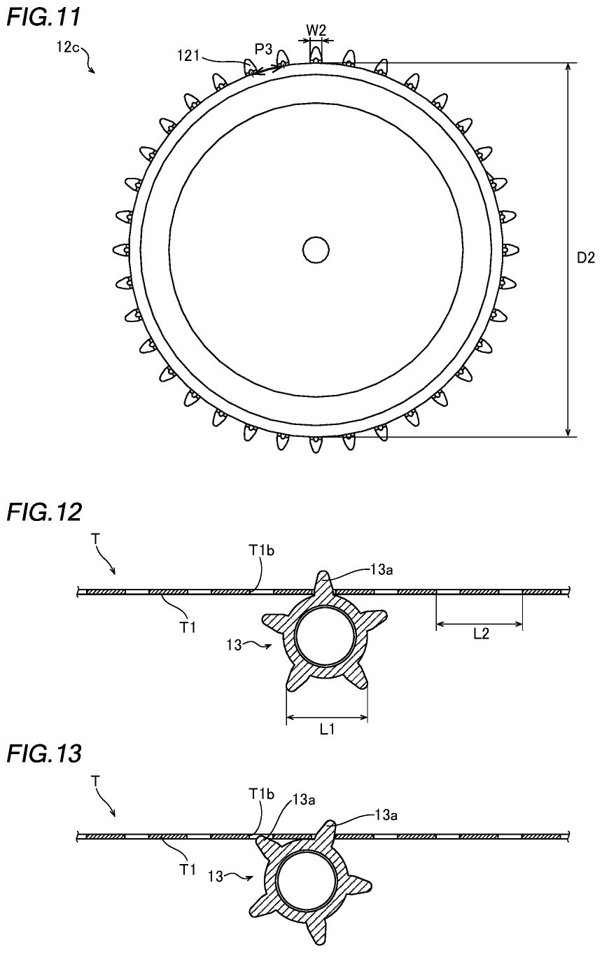

As shown in FIGS. 10 and 11, the discharge sprockets 13 are smaller than the sprocket 12c (12b). Specifically, the diameter D1 of each of the discharge sprockets 13 is smaller than the diameter D2 of the sprocket 12c (12b). The number of teeth 13a of each of the discharge sprockets 13 is less than the number of teeth 121 of the sprocket 12c (12b).

In the first embodiment, a pitch P2 between the teeth 13a of each of the discharge sprockets 13 is smaller than a pitch P3 between the teeth 121 of the sprocket 12c (12b). That is, the pitch P2 between the teeth 13a of the discharge sprocket 13 is smaller than the pitch P1 (see FIG. 4) between the sprocket holes T1b of the component supply tape T. The pitch P3 between the teeth 121 of the sprocket 12c (12b) is substantially equal to the pitch P1 between the sprocket holes T1b of the component supply tape T. Although the pitches P1, P2, and P3 are not particularly limited, the pitches P1 and P3 are about 4 mm, and the pitch P2 is about 3.5 mm, for example. The pitches P2 and P3 refer to lengths in the circumferential direction between the roots of adjacent teeth of the sprockets. The width W1 of each of the teeth 13a of the discharge sprocket 13 is smaller than the width W2 of each of the teeth 121 of the sprocket 12c (12b). Specifically, the teeth 13a of the discharge sprocket 13 are thinner than the teeth 121 of the sprocket 12c (12b) from the roots to the tip ends.

The relationship between the pitch P2 between the teeth 13a of the discharge sprocket 13 and the sprocket holes T1b of the component supply tape T is now described with reference to FIGS. 12 to 15.

The teeth 13a of the discharge sprocket 13 need to have a certain height in order to be inserted into the sprocket holes T1b of the two component supply tapes T. On the other hand, the discharge sprocket 13 is smaller than the sprocket 12c (12b), and thus unlike the sprocket 12c (12b), there is a large difference between the pitch between the tip ends of the teeth 13a and the pitch (P2) between the roots of the teeth 13a. Therefore, when the pitch P2 between the teeth 13a of the discharge sprocket 13 is substantially the same as the pitch P3 between the teeth 121 of the sprocket 12c (12b), it is difficult to insert the teeth 13a of the discharge sprocket 13 into the sprocket holes T1b of the component supply tape T one after another.

Therefore, in the first embodiment, as described above, the pitch P2 between the teeth 13a of the discharge sprocket 13 is smaller than the pitch P3 between the teeth 121 of the sprocket 12c (12b). Thus, the teeth 13a of the discharge sprocket 13 can be inserted into the sprocket holes T1b of the component supply tape T one after another.

As shown in FIGS. 12 and 13, the pitch P2 between the teeth 13a of the discharge sprocket 13 is 3.5 mm, and a length L1 between the outer sides of the tip ends of the adjacent teeth 13a is 5.3 mm, for example. Furthermore, the pitch P1 between the sprocket holes T1b of the component supply tape T (and the pitch P2 of the sprocket 12c (12b)) is 4 mm, and a length L2 between the outer sides of the adjacent sprocket holes T1b is 5.5 mm, for example. In this case, the length L1 between the outer sides of the tip ends of the adjacent teeth 13a of the discharge sprocket 13 is smaller than the length L2 between the outer sides of the adjacent sprocket holes T1b of the component supply tape T, and thus the teeth 13a of the discharge sprocket 13 can be inserted into the sprocket holes T1b of the component supply tape T one after another. The pitch P2 between the teeth 13a of the discharge sprocket 13 is 3.5 mm while the pitch P1 between the sprocket holes T1b of the component supply tape T is 4 mm, and thus the pitches do not match. However, when the teeth 13a are inserted into the sprocket holes T1b, slippage occurs between the discharge sprocket 13 and the component supply tape T, and thus the teeth 13a of the discharge sprocket 13 can be inserted into the sprocket holes T1b of the component supply tape T one after another.

In the first embodiment, the pitch P2 between the teeth 13a of the discharge sprocket 13 is smaller than the pitch P3 between the teeth 121 of the sprocket 12c (12b), and thus the length L1 between the outer sides of the tip ends of the adjacent teeth 13a of the discharge sprocket 13 is smaller than the length L2 between the outer sides of the adjacent sprocket holes T1b of the component supply tape T.

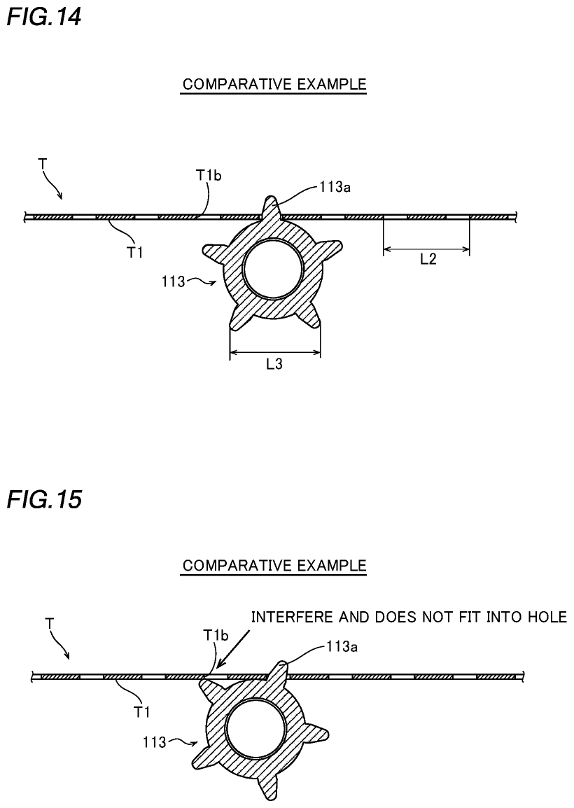

On the other hand, as shown in FIGS. 14 and 15, in a comparative example, a pitch between teeth 113a of a discharge sprocket 113 is 4 mm, and a length L3 between the outer sides of tip ends of the adjacent teeth 113a is 5.9 mm. The pitch P1 between the sprocket holes T1b of the component supply tape T (and the pitch P2 of the sprocket 12c (12b)) is 4 mm, and the length L2 between the outer sides of the adjacent sprocket holes T1b is 5.5 mm. In this case, the length L3 between the outer sides of the tip ends of the adjacent teeth 113a of the discharge sprocket 113 is smaller than the length L2 between the outer sides of the adjacent sprocket holes T1b of the component supply tape T, and thus the tooth 113a of the discharge sprocket 113 interferes with the sprocket hole T1b of the component supply tape T, and the teeth 113a of the discharge sprocket 113 cannot be inserted into the sprocket holes T1b of the component supply tape T one after another.

### Advantageous Effects of First Embodiment

According to the first embodiment, the following advantageous effects are achieved.

According to the first embodiment, as described above, the discharge sprockets 13 are provided in the discharge passage 11d. Each of the discharge sprockets 13 has the teeth 13a that are insertable simultaneously into the sprocket holes T1b of both the following tape Tb corresponding to the subsequent component supply tape T in use and the leading tape Ta corresponding to the used preceding component supply tape T. The component supplier 10 is operable to rotate the discharge sprockets 13 to feed the leading tape Ta in the discharge passage 11d. Accordingly, even when the following tape Tb rides on the leading tape Ta to overlap the leading tape Ta, for example, the leading tape Ta can be fed by the discharge sprockets 13. Consequently, even when the following tape Tb overlaps the leading tape Ta, the leading tape Ta can be smoothly discharged from the discharge passage 11d. Furthermore, an error caused by not discharging the leading tape Ta can be reduced or prevented, and thus a decrease in the productivity of the component mounting device 100 can be reduced or prevented.

According to the first embodiment, as described above, each of the discharge sprockets 13 does not have power, and the component supplier 10 is operable to rotate the discharge sprockets 13 to feed the leading tape Ta in the discharge passage 11 by feeding the following tape Tb by the driving force of the sprocket 12c (12b) while the teeth 13a of the discharge sprockets 13 are inserted simultaneously into the sprocket holes T1b of both the following tape Tb and the leading tape Ta. Accordingly, unlike a case in which each of the discharge sprockets 13 has power, it is not necessary to provide a drive such as a motor to drive each of the discharge sprockets 13. Consequently, the structure of a discharge mechanism including the discharge sprockets 13 can be simplified and downsized. Furthermore, being able to downsize the discharge mechanism including the discharge sprockets 13 is very effective when the discharge sprockets 13 are provided in the discharge passage 11d in which an installation space is relatively small.

According to the first embodiment, as described above, the height H of each of the teeth 13a is larger than the thickness Th of the component supply tape T. Accordingly, unlike a case in which the heights H of each of the teeth 13a of each of the discharge sprockets 13 is equal to or less than the thickness Th of the component supply tape T, the teeth 13a of the discharge sprocket 13 can be reliably inserted simultaneously into both the sprocket holes T1b of both the following tape Tb (components supply tape T) and the leading tape Ta (components supply tape T). Consequently, both the following tape Tb and the leading tape Ta can be reliably fed by rotation of the discharge sprocket 13.

According to the first embodiment, as described above, the component supplier 10 includes the urging force generator 14f to urge one of the discharge sprocket 13 and the component supply tape T toward the other of the discharge sprocket 13 and the component supply tape T. Accordingly, due to the urging force of the urging force generator 14f, the discharge sprocket 13 and the component supply tape T can be placed close to each other. Consequently, the teeth 13a of the discharge sprocket 13 can be reliably inserted into the sprocket holes T1b of the component supply tape T.

According to the first embodiment, as described above, the diameter D1 of the discharge sprocket 13 is smaller than the diameter D2 of the sprocket 12c (12b). Furthermore, the number of teeth 13a of the discharge sprocket 13 is less than the number of teeth 121 of the sprocket 12c (12b). Accordingly, the discharge sprocket 13 can be downsized. Consequently, the discharge sprocket 13 can be easily arranged even in the discharge passage 11d in which the installation space is relatively small.

According to the first embodiment, as described above, the pitch P2 between the teeth 13a of the discharge sprocket 13 is smaller than the pitch P3 between the teeth 121 of the sprocket 12c (12b). In the small discharge sprocket 13 having a smaller diameter than the sprocket 12c (12b), when the pitch P2 between the teeth 13a is the same as the pitch (P3) between (the roots of) the teeth of the large sprocket 12c (12b) having a larger diameter, the tip ends of the teeth 13a may be too far apart unlike the sprocket 12c (12b) that is larger than the discharge sprocket 13. Therefore, the teeth 13a of the discharge sprocket 13 may not be inserted (fitted) into the sprocket holes T1b of the component supply tape T one after another. Therefore, as described above, the pitch between the teeth 13a of the discharge sprocket 13 is smaller than the pitch between the teeth 121 of the sprocket 12c (12b). Thus, even when the discharge sprocket 13 is smaller than the sprocket 12c (12b), the teeth 13a of the discharge sprocket 13 can be inserted (fitted) into the sprocket holes T1b of the component supply tape T one after another. Consequently, the component supply tape T (the following tape Tb and the leading tape Ta) can be reliably fed by rotation of the discharge sprocket 13.

According to the first embodiment, as described above, the width W1 of each of the teeth 13a of the discharge sprocket 13 is smaller than the width W2 of each of the teeth 121 of the sprocket 12c (12b). Accordingly, the width of each of the teeth 13a of the discharge sprocket 13 can be relatively small. Consequently, the teeth 13a of the discharge sprocket 13 can be more easily inserted (fitted) into the sprocket holes T1b of the component supply tape T as compared with a case in which the width of each of the teeth 13a of the discharge sprocket 13 is relatively large.

According to the first embodiment, as described above, the component supplier 10 includes the bending habit correction mechanism 14 in the discharge passage 11d to correct the bending habit of the component supply tape T. Furthermore, the discharge sprocket 13 is provided in the discharge passage 11d together with the bending habit correction mechanism 14. Accordingly, even when the bending habit correction mechanism 14 is provided such that the discharge passage 11d becomes complex, the leading tape Ta can be smoothly discharged from the discharge passage 11d by the discharge sprocket 13.

### Second Embodiment

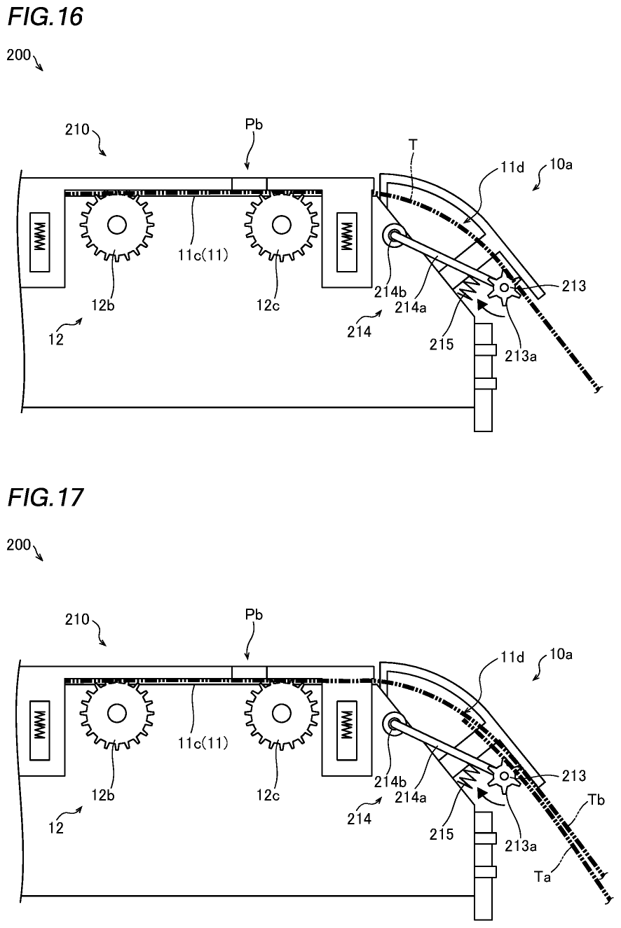

A second embodiment is now described with reference to FIGS. 16 and 17. In the second embodiment, an example is described in which a bending habit correction mechanism is not provided in a discharge passage, unlike the first embodiment in which the bending habit correction mechanism is provided in the discharge passage. The same or similar structures as those of the first embodiment are denoted by the same reference numerals, and detailed description thereof is omitted.

### Structure of Component Mounting Device

A component mounting device 200 according to the second embodiment of the present disclosure includes a component supplier 210 instead of the component supplier 10 according to the first embodiment, as shown in FIGS. 16 and 17. The component supplier 210 is an example of a “component supply device” in the claims.

In the second embodiment, the component supplier 210 does not include the bending habit correction mechanism 14 according to the first embodiment in a discharge passage 11d. The component supplier 210 includes a main body 10a, a tape passage 11, a tape feeding mechanism 12, a discharge sprocket 213, a lever mechanism 214, and an urging force generator 215.

In the second embodiment, the discharge sprocket 213 is provided in the discharge passage 11d. The discharge sprocket 213 has teeth 213a that can be inserted simultaneously into sprocket holes T1b of both a following tape Tb that is a subsequent component supply tape T in use and a leading tape Ta that is a used preceding component supply tape T. In the component supplier 210, the leading tape Ta in the discharge passage 11d is fed by rotating the discharge sprocket 213.

In the second embodiment, the discharge sprocket 213 does not have power (is not driven by a motor). Furthermore, in the component supplier 210, the following tape Tb is fed by the driving force of sprockets 12b and 12c (the driving force of a drive motor 12e) while the teeth 213a of the discharge sprocket 213 are inserted simultaneously into the sprocket holes T1b of both the following tape Tb and the leading tape Ta such that the discharge sprocket 213 is rotated to feed the leading tape Ta in the discharge passage 11d.

Specifically, in the component supplier 210, when the following tape Tb is fed while the teeth 213a of the discharge sprocket 213 are inserted simultaneously into the sprocket holes T1b of both the following tape Tb and the leading tape Ta, the sprocket holes T1b of the following tape Tb contact the teeth 213a of the discharge sprocket 213 such that the driving force of the following tape Tb is transmitted to the discharge sprocket 213, and the discharge sprocket 213 is rotated. Furthermore, in the component supplier 210, when the sprocket holes T1b of the following tape Tb contact the teeth 213a of the discharge sprocket 213 such that the discharge sprocket 213 is rotated, the teeth 13a of the discharge sprocket 213 contact the sprocket holes T1b of the leading tape Ta. Thus, the driving force of the discharge sprocket 213 is transmitted to the leading tape Ta, and the leading tape Ta overlapping the following tape Tb in the discharge passage 11d is fed.

One discharge sprocket 213 is provided. The discharge sprocket 213 is provided in the vicinity of an exit of the discharge passage 11d. Furthermore, the teeth 213a of the discharge sprocket 213 are inserted into the sprocket holes T1b of the component supply tape T from below. The discharge sprocket 213 has a plurality of teeth 213a. The plurality of teeth 213a are provided at substantially equal angular intervals in a circumferential direction.

The lever mechanism 214 includes a lever 214a and a rotation shaft 214b. The lever 214a is rotatably supported by the rotation shaft 214b. Furthermore, the lever 214a is rotatable about the rotation shaft 214b by the urging force of the urging force generator 215. The discharge sprocket 213 is integrally and rotatably provided on the lever 214a. The rotation shaft 214b is provided at a first end of the lever 214a, and the discharge sprocket 213 is provided at a second end of the lever 214a. The lever 214e presses the discharge sprocket 213 against the component supply tape T by the urging force of the urging force generator 14f.

The urging force generator 215 is a coil spring having an urging force. The urging force generator 215 urges the lever 214a. Specifically, the urging force generator 215 urges the discharge sprocket 213 toward the component supply tape T via the lever 214a. Furthermore, it is possible to handle component supply tapes T having different thicknesses by the urging force of the urging force generator 215.

The remaining structures of the second embodiment are similar to those of the first embodiment.

### Advantageous Effects of Second Embodiment

According to the second embodiment, the following advantageous effects are achieved.

According to the second embodiment, as described above, the discharge sprocket 213 is provided in the discharge passage 11d. Furthermore, the discharge sprocket 213 has the teeth 213a that are insertable simultaneously into the sprocket holes T1b of both the following tape Tb corresponding to the subsequent component supply tape T in use and the leading tape Ta corresponding to the used preceding component supply tape T. The component supplier 210 is operable to rotate the discharge sprocket 213 to feed the leading tape Ta in the discharge passage 11d. Accordingly, similarly to the first embodiment, even when the following tape Tb overlaps the leading tape Ta, the leading tape Ta can be smoothly discharged from the discharge passage 11d. Furthermore, an error caused by not discharging the leading tape Ta can be reduced or prevented, and thus a decrease in the productivity of the component mounting device 200 can be reduced or prevented.

The remaining advantageous effects of the second embodiment are similar to the advantageous effects of the first embodiment.

### Modified Examples

The embodiments disclosed this time must be considered as illustrative in all points and not restrictive. The scope of the present disclosure is not shown by the above description of the embodiments but by the scope of claims for patent, and all modifications (modified examples) within the meaning and scope equivalent to the scope of claims for patent are further included.

For example, while the example in which the discharge sprocket is provided in the vicinity of the central portion of the discharge passage or in the vicinity of the exit of the discharge passage has been shown in each of the aforementioned first and second embodiments, the present disclosure is not restricted to this. For example, the discharge sprocket may be provided in the vicinity of an entrance of the discharge passage. However, from the viewpoint of smoothly discharging the leading tape in the discharge passage, it is preferable to provide the discharge sprocket relatively downstream in the feeding direction in the discharge passage.

While the example in which the width of each of the teeth of the discharge sprocket is smaller than the width of each of the teeth of the feed sprocket has been shown in each of the aforementioned first and second embodiments, the present disclosure is not restricted to this. For example, the width of each of the teeth of the discharge sprocket may be substantially the same as or larger than the width of each of the teeth of the feed sprocket.

While the example in which two feed sprockets are provided in the vicinity of the component supply position has been shown in each of the aforementioned first and second embodiments, the present disclosure is not restricted to this. For example, only one feed sprocket may be provided in the vicinity of the component supply position.

While the example in which two discharge sprockets are provided has been shown in the aforementioned first embodiment, and the example in which one discharge sprocket is provided has been shown in the aforementioned second embodiment, the present disclosure is not restricted to this. For example, in the aforementioned first embodiment, one or three or more discharge sprockets may be provided. Furthermore, in the structure of the second embodiment, two or more discharge sprockets may be provided.

While the example in which the urging force generator is provided to urge one of the discharge sprocket and the component supply tape toward the other of the discharge sprocket and the component supply tape has been shown in each of the aforementioned first and second embodiments, the present disclosure is not restricted to this. For example, when the teeth of the discharge sprocket can be inserted simultaneously into the sprocket holes of the two component supply tapes without providing the urging force generator, the urging force generator may not be provided to urge one of the discharge sprocket and the component supply tape toward the other of the discharge sprocket and the component supply tape.

While the example in which the bending habit correction mechanism includes three rollers has been shown in the aforementioned first embodiment, the present disclosure is not restricted to this. For example, the bending habit correction mechanism may include one roller or a number of rollers other than three.

While the example in which the discharge sprocket and the roller of the bending habit correction mechanism are supported by the common rotation shaft has been shown in the aforementioned first embodiment, the present disclosure is not restricted to this. For example, the discharge sprocket and the roller of the bending habit correction mechanism may be supported by separate rotation shafts.

What is claimed is:

1. A component supply device comprising:
a feed sprocket to feed a component supply tape holding a component to a component supply position, and feed the component supply tape from which the component has been taken out at the component supply position toward a discharge passage; and
a discharge sprocket in the discharge passage; wherein
the discharge sprocket has teeth that are insertable simultaneously into sprocket holes of both a following tape corresponding to a subsequent component supply tape in use and a leading tape corresponding to a used preceding component supply tape; and
the component supply device is operable to rotate the discharge sprocket to feed the leading tape in the discharge passage.

2. The component supply device according to claim 1, wherein
the discharge sprocket does not have power; and
the component supply device is operable to rotate the discharge sprocket to feed the leading tape in the discharge passage by feeding the following tape by a driving force of the feed sprocket while the teeth of the discharge sprocket are inserted simultaneously into the sprocket holes of both the following tape and the leading tape.

3. The component supply device according to claim 1,
wherein a height of each of the teeth is larger than a thickness of the component supply tape.

4. The component supply device according to claim 1, further comprising:
an urging force generator to urge one of the discharge sprocket and the component supply tape toward the other of the discharge sprocket and the component supply tape.

5. The component supply device according to claim 1, wherein
a diameter of the discharge sprocket is smaller than a diameter of the feed sprocket; and
a number of the teeth of the discharge sprocket is less than a number of teeth of the feed sprocket.

6. The component supply device according to claim 5, wherein a pitch between the teeth of the discharge sprocket is smaller than a pitch between the teeth of the feed sprocket.

7. The component supply device according to claim 6, wherein a width of each of the teeth of the discharge sprocket is smaller than a width of each of the teeth of the feed sprocket.

8. The component supply device according to claim 1, further comprising:
a bending habit correction mechanism in the discharge passage to correct a bending habit of the component supply tape; wherein
the discharge sprocket is provided in the discharge passage together with the bending habit correction mechanism.

9. A component mounting device comprising:
a mounting head to hold and mount a component on a board; and
a component supplier to supply the component to the mounting head; wherein
the component supplier includes:
a feed sprocket to feed a component supply tape holding the component to a component supply position, and feed the component supply tape from which the component has been taken out at the component supply position toward a discharge passage; and
a discharge sprocket in the discharge passage;
the discharge sprocket has teeth that are insertable simultaneously into sprocket holes of both a following tape corresponding to the subsequent component supply tape in use and a leading tape corresponding to the used preceding component supply tape; and
the component supplier is operable to rotate the discharge sprocket to feed the leading tape in the discharge passage.

10. The component mounting device according to claim 9, wherein
the discharge sprocket does not have power; and
the component supplier is operable to rotate the discharge sprocket to feed the leading tape in the discharge passage by feeding the following tape by a driving force of the feed sprocket while the teeth of the discharge sprocket are inserted simultaneously into the sprocket holes of both the following tape and the leading tape.

11. The component supply device according to claim 2, wherein a height of each of the teeth is larger than a thickness of the component supply tape.

12. The component supply device according to claim 2, further comprising:
an urging force generator to urge one of the discharge sprocket and the component supply tape toward the other of the discharge sprocket and the component supply tape.

13. The component supply device according to claim 3, further comprising:
an urging force generator to urge one of the discharge sprocket and the component supply tape toward the other of the discharge sprocket and the component supply tape.

14. The component supply device according to claim 2, wherein
a diameter of the discharge sprocket is smaller than a diameter of the feed sprocket; and
a number of the teeth of the discharge sprocket is less than a number of teeth of the feed sprocket.

15. The component supply device according to claim 3, wherein
a diameter of the discharge sprocket is smaller than a diameter of the feed sprocket; and
a number of the teeth of the discharge sprocket is less than a number of teeth of the feed sprocket.

16. The component supply device according to claim 4, wherein
a diameter of the discharge sprocket is smaller than a diameter of the feed sprocket; and
a number of the teeth of the discharge sprocket is less than a number of teeth of the feed sprocket.

17. The component supply device according to claim 2, further comprising:
a bending habit correction mechanism in the discharge passage to correct a bending habit of the component supply tape; wherein
the discharge sprocket is in the discharge passage together with the bending habit correction mechanism.

18. The component supply device according to claim 3, further comprising:
a bending habit correction mechanism in the discharge passage to correct a bending habit of the component supply tape; wherein
the discharge sprocket is in the discharge passage together with the bending habit correction mechanism.

19. The component supply device according to claim 4, further comprising:
a bending habit correction mechanism in the discharge passage to correct a bending habit of the component supply tape; wherein
the discharge sprocket is in the discharge passage together with the bending habit correction mechanism.

20. The component supply device according to claim 5, further comprising:
a bending habit correction mechanism in the discharge passage to correct a bending habit of the component supply tape; wherein
the discharge sprocket is in the discharge passage together with the bending habit correction mechanism.
